(19) United States
(12) Patent Application Publication
(10) Pub. No.: US 2024/0302262 A1
(43) Pub. Date: Sep. 12, 2024

(54) METHOD AND SYSTEM FOR IDENTIFYING GLACIAL LAKE OUTBURST DEBRIS FLOW

(71) Applicant: Kunming University of Science and Technology, Kunming (CN)

(72) Inventors: Zhi-quan Yang, Kunming (CN); Zi-xu Zhang, Kunming (CN); Wen-qi Jiao, Kunming (CN); Ying-yan Zhu, Kunming (CN); Muhammad Asif Khan, Kunming (CN); Yong-shun Han, Kunming (CN); Li-ping Liao, Kunming (CN); Jie Zhang, Kunming (CN); Wen-fei Xi, Kunming (CN); Han-hua Xu, Kunming (CN); Tian-bing Xiang, Kunming (CN); Xin Zhao, Kunming (CN); Bi-hua Zhang, Kunming (CN); Shen-zhang Liu, Kunming (CN); Cheng-yin Ye, Kunming (CN)

(21) Appl. No.: 18/599,211

(22) Filed: Mar. 8, 2024

(30) Foreign Application Priority Data
Mar. 9, 2023 (CN) 202310220685X

(51) Int. Cl. G01N 15/02; G06F 17/11

(52) U.S. Cl. CPC G01N 15/0272; G06F 17/11; E02B 1/00; E02B 5/00; E02B 5/08; E02B 5/085; E02B 8/02; E02B 8/06; G01M 10/00; G01N 2015/0277; G06F 30/13; G06F 30/20; G06F 30/23; G06F 30/28; G06Q 10/04; G08B 21/10

(57) ABSTRACT

A method and a system for identifying a glacial lake outburst debris flow (GLODF) are provided. The method is obtained based on considering induced influences of slopes of channels and particle sizes of source particles on the GLODF. The method not only compensates for deficiencies in identifying the GLODF, but also realizes determination of the GLODF, which provides data basis for disaster prevention and control layout such as monitoring and early warning on a glacial lake and assists preventing and managing disasters caused by the GLODF. Meanwhile, multiple parameters used in the method are easy and convenient to obtain, and the parameters can be directly used on site, which saves engineering cost, improves working efficiency, and has high practical and promotional value in environmental protection and disaster prevention and mitigation.

### TECHNICAL FIELD

The disclosure relates to the technical field of environmental protection and disaster prevention and mitigation, particularly to a method and a system for identifying a glacial lake outburst debris flow (GLODF).

### BACKGROUND

Debris flow refers to a special type of flood that occurs in valleys or slopes due to snow melting, glacial lake burst, precipitation, etc., bringing out a large amount of solid substances such as mud, sand, stones, and boulders. As a catastrophic geological phenomenon with strong destructive power, the debris flow not only has characteristics of fast flow velocity, large flow, large material capacity, and strong destructive power, but also has characteristics of unpredictability such as suddenness.

Specially, the GLODF is a sudden geological disaster that develops in high mountain continental glacier areas, characterized by large scale, fast speed, and strong destruction. In the world, the GLODF is mainly distributed in rapidly declining modern glaciers such as Caucasus Mountains and outer Ili Mountain, Pacific Coastal Mountainous Area in the United States, State of Alaska, and mountainous areas of northwestern Venezuela in South America. As for China, the GLODF is widely developed in the glaciers such as Mount Nyenchen Tanglha, Hengduan Mountains, Har goolun Range, Altai Mountains, Tianshan Mountains, and Qilian Mountains, and the GLODF seriously affects safety of people's lives and property.

Currently, main methods proposed in the field of debris flow identification are aimed at identifying rainfall type debris flows. However, there is no relevant research and discussion on the method for identifying the GLODF. Therefore, there is an urgent need for a method and a system for identifying the GLODF, so as to further perform disaster prevention and control layout such as monitoring and early warning on the corresponding glacial lake, thereby to assist preventing and managing disasters caused by the GLODF.

### SUMMARY

In view of the deficiencies in the related art and the requirements of practical application and in order to identify the GLODF, so as to further perform disaster prevention and control layout such as monitoring and early warning on the corresponding glacial lake, thereby to assist preventing and managing disasters caused by the GLODF, on the one hand, the disclosure provides a method for identifying the GLODF, including the following steps: calibrating a to-be-identified drainage basin, positioning channels of the to-be-identified drainage basin, and identifying source particles in the channels; constructing a slope coefficient model for the channels of the to-be-identified drainage basin by using slopes of the channels; constructing an equivalent particle size model of the source particles by using geometric features of the source particles; constructing an identification model for the GLODF in combination with the slope coefficient model for the channels of the to-be-identified drainage basin and the equivalent particle size model of the source particles; measuring slope data corresponding to the channels, and then obtaining a slope coefficient for the channels of the to-be-identified drainage basin by using the slope data in combination with the slope coefficient model for the channels of the to-be-identified drainage basin; measuring the geometric features of the source particles, and then obtaining an equivalent particle size of the source particles of the to-be-identified drainage basin by using the geometric features of the source particles in combination with the equivalent particle size model of the source particles; and determining, based on the slope coefficient for the channels of the to-be-identified drainage basin, the equivalent particle size of the source particles, and the identification model for the GLODF, whether the to-be-identified drainage basin is a glacial lake outburst debris flow basin. On a basis of considering induced influences of the slopes of the channels and the particle sizes of the source particles on the glacial lake outburst debris flow, the disclosure provides a method for identifying the GLODF. Therefore, the method provided by the disclosure not only compensates for the deficiencies in identifying the GLODF in the related art, but also realizes the determination of the GLODF, which provides data basis for the disaster prevention and the control layout such as monitoring and early warning on the corresponding glacial lake, as well as assists preventing and managing the disasters caused by the GLODF. Meanwhile, multiple parameters used in the method provided by the disclosure are easy and convenient to obtain, and the obtained parameters can be directly used on site, which saves engineering cost and improves working efficiency. Thus, the disclosure has high practical and promotional value in the technical field of environmental protection and disaster prevention and mitigation.

In an embodiment, the method further includes: performing, by workers, disaster prevention and control layout upon determining the to-be-identified drainage basin as the glacial lake outburst debris flow basin.

In an embodiment, the to-be-identified drainage basin includes: a drainage basin to be determined whether the GLODF occurs, and a drainage basin that a debris flow has occurred but the debris flow is not determined whether being the GLODF.

In an embodiment, the calibrating a to-be-identified drainage basin, positioning channels of the to-be-identified drainage basin, and identifying source particles in the channels includes the following steps:
obtaining an integrated condition of the to-be-identified drainage basin, which includes: a number, a distribution, and the slopes of the channels of the to-be-identified drainage basin, and a number, sizes, and a distribution of rock particles in the channels;
positioning the channels of the to-be-identified drainage basin through the integrated condition; and
screening the source particles in the channels according to the number, the sizes, and the distribution of the rock particles in the channels.

In an embodiment, the slope coefficient model for the channels of the to-be-identified drainage basin is expressed by the following formula:

$$C = \frac{1}{cos α - sin α} .$$

In the above formula, C represents the slope coefficient for the channels of the to-be-identified drainage basin; and α represents an average slope of the to-be-identified drainage basin.

In an embodiment, the constructing a slope coefficient model for the channels of the to-be-identified drainage basin by using slopes of the channels further includes the following steps:
determining an upper reach and a lower reach of the to-be-identified drainage basin according to positioning results of the channels of the to-be-identified drainage basin, and setting the upper reach and the lower reach as a starting point and an ending point, respectively;
segmenting the to-be-identified drainage basin by using the starting point and the ending point to obtain multiple segments;
setting a slope weighting coefficient corresponding to each of the multiple segments according to a segmentation result; and
summarizing the slopes of the channels in each of the multiple segments of the to-be-identified drainage basin and the slope weighting coefficients corresponding to the multiple segments to update the slope coefficient model for the channels of the to-be-identified drainage basin, thereby obtaining an updated slope coefficient model for the channels of the to-be-identified drainage basin.

In an embodiment, the updated slope coefficient model for the channels of the to-be-identified drainage basin is expressed by the following formula:

$$C = \frac{\sqrt{2}}{2 cos [ \frac{1}{n} {\sum }_{i = 1}^{n} {{k}_{i} ( \frac{1}{m} {\sum }_{t = 1}^{m} {θ}_{t} )}_{i} + \frac{π}{4} ]} .$$

In the above formula, C represents the slope coefficient for the channels of the to-be-identified drainage basin; i=1, 2, . . . , n, and n represents a total number of the multiple segments in the to-be-identified drainage basin; kᵢ≥1, and kᵢ represents the slope weighting coefficient corresponding to an i^{th} segment of the to-be-identified drainage basin;

$${( \frac{1}{m} {\sum }_{t = 1}^{m} {θ}_{t} )}_{i}$$

represents an average value of the slopes in the i^{th} segment of the to-be-identified drainage basin, t=1, 2, . . . , m, m represents a number of the channels contained in the corresponding segment of the to-be-identified drainage basin, and θₜ represents a slope of a t^{th} channel.

In an embodiment, the equivalent particle size model of the source particles is expressed by the following formula:

$$D = {( \frac{6 abc}{π} )}^{1 / 3} .$$

In the above formula, D represents the equivalent particle size of the source particles; a represents an average length of the source particles, b represents an average width of the source particles, and c represents an average height of the source particles.

In an embodiment, the constructing an equivalent particle size model of the source particles by using geometric features of the source particles further includes the following steps:
identifying types of the source particles in the channels, and obtaining distribution data of the types of the source particles;
setting, according to the distribution data of the types of the source particles, source particles with a maximum number distributed in the channels as target source particles;
setting a center position of the target source particles in contact with ground as an origin, setting an edge that the target source particles are parallel to the ground as a horizontal axis, and setting a longitudinal axis according to the origin and the horizontal axis, and setting a vertical axis according to the origin, the horizontal axis, and the longitudinal axis, thereby establishing an evaluation coordinate system;
projecting the target source particles on different two-dimensional planes of the evaluation coordinate system, respectively, and obtaining geometric features of the target source particles according to a projection result;
obtaining average geometric features of the target source particles by summarizing and averaging the geometric features of the target source particles, including: an average length, an average width, and an average height; and
updating the equivalent particle size model of the source particles by using the average geometric features, thereby obtaining an updated equivalent particle size model of the source particles.

In an embodiment, the updated equivalent particle size model of the source particles is expressed by the following formula:

$$D = {{{Q}^{- 1} ( 6 / π )}^{1 / 3} [ {\sum }_{j = 1}^{Q} {a}_{j}^{′} {\sum }_{j = 1}^{Q} {b}_{j}^{′} {\sum }_{j = 1}^{Q} {c}_{j}^{′} ]}^{1 / 3} .$$

In the above formula, D represents the equivalent particle size of the source particles; j=1, 2, . . . , Q, and Q represents a total number of the target source particles; a′ⱼ represents a length of a j^{th} target source particle, b′ⱼ represents a width of the j^{th} target source particle, and c′ⱼ represents a height of the j^{th} target source particle.

In an embodiment, the identification model for the GLODF is expressed by the following formula:

$$ω = \frac{{( D - 5.5 )}^{2}}{{( 4.5 )}^{2}} + {( C - 2 )}^{2} .$$

In the above formula, w represents an identification index for the GLODF; C represents the slope coefficient for the channels of the to-be-identified drainage basin obtained by the slope coefficient model for the channels of the to-be-identified drainage basin; and D represents the equivalent particle size of the source particles obtained by the equivalent particle size model of the source particles.

In an embodiment, the determining, based on the slope coefficient for the channels of the to-be-identified drainage basin, the equivalent particle size of the source particles, and the identification model for the GLODF, whether the to-be-identified drainage basin is a glacial lake outburst debris flow basin includes the following steps:
substituting the slope coefficient for the channels of the to-be-identified drainage basin and the equivalent particle size of the source particles into the identification model for the GLODF to obtain the identification index for the GLODF;
determining, in response to the identification index for the GLODF being less than or equal to 1, the to-be-identified drainage basin as the glacial lake outburst debris flow basin; and
determining, in response to the identification index for the GLODF being greater than 1, the to-be-identified drainage basin as a non-glacial lake outburst debris flow basin.

On the other hand, the disclosure further provides a system for identifying a GLODF, including: a processor, an input device, an output device, and a memory; the processor, the input device, the output device, and the memory are connected to each other; the memory is configured to store a computer program, the computer program includes program instructions, and the processor is configured to call the program instructions to execute the method for identifying the GLODF as described above. The system for identifying the GLODF provided by the disclosure is compact in structure, stable and rapid in operation, and can well execute the method for identifying the GLODF.

### BRIEF DESCRIPTION OF DRAWING

FIG. 1 illustrates a flowchart of a method for identifying a GLODF according to the disclosure.

FIG. 2 illustrates a schematic diagram of an evaluation coordinate system according to an embodiment of the disclosure.

FIG. 3 illustrates a schematic structural diagram of a system for identifying a GLODF according to the disclosure.

### DETAILED DESCRIPTION OF EMBODIMENTS

Illustrated embodiments of the disclosure will be described in detail below, and it should be noted that the embodiments described herein are only for illustration and are not intended to limit the disclosure. In the following description, numerous specific details are set forth in order to provide a thorough understanding of the disclosure. It will be apparent, however, to those skilled in the related art that the disclosure may be practiced without these specific details. In other embodiments, well-known circuits, software, or methods are not specifically described in order to avoid obscuring the disclosure.

Throughout this specification, terms of “an embodiment”, “embodiments”, “an example”, or “examples” mean that a particular feature, structure, or characteristic described in connection with the embodiment or example is included in at least one embodiment of the disclosure. Thus, appearances of phrases “in an embodiment”, “in embodiments”, “an example”, or “examples” in various places throughout the specification are not necessarily all referring to the same embodiment or example. Furthermore, the particular feature, structure, or characteristic may be combined in one or more embodiments or examples in any suitable combination or sub-combination. Furthermore, those skilled in the related art will appreciate that attached drawings provided herein are used for illustrative purposes and that the attached drawings are not necessarily drawn to scale.

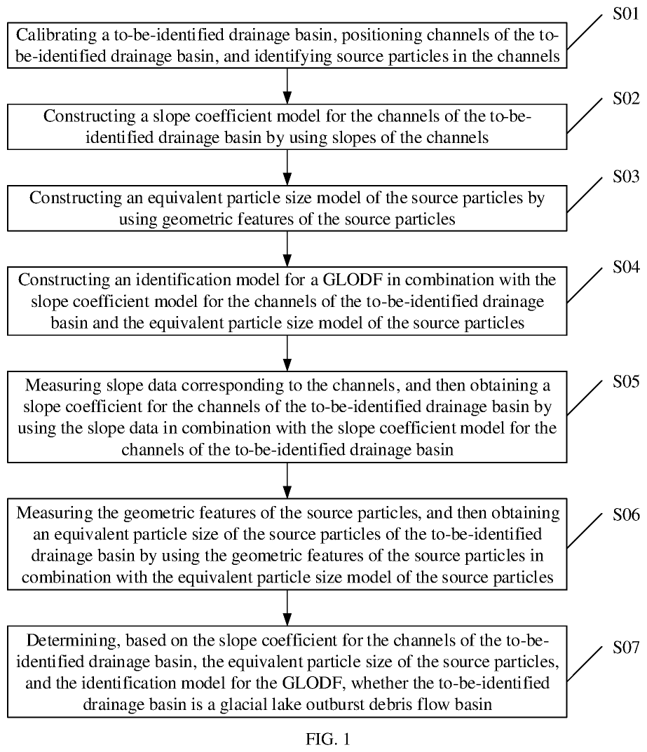

In order to identify GLODFs, so as to further perform disaster prevention and control layout such as monitoring and early warning on the corresponding glacial lake, thereby to assist preventing and managing disasters caused by the GLODFs, the disclosure provides a method for identifying the GLODFs, aiming at identifying and assessing the GLODFs. With reference to FIG. 1, the method for identifying the GLODFs according to the disclosure includes the following steps.

Step 1, a to-be-identified drainage basin is calibrated, channels of the to-be-identified drainage basin are positioned, and source particles in the channels are identified.

It should be understood that the to-be-identified drainage basin includes: a drainage basin to be determined whether the GLODF occurs, and a drainage basin that a debris flow has occurred but the occurred debris flow is not determined whether being the GLODF. Moreover, the drainage basin to be determined whether the GLODF occurs is identified by the method provided by the disclosure; if an identification result is that the drainage basin is a glacial lake outburst debris flow basin, it is indicated that the drainage basin has occurred the GLODF; and if an identification result is a non-glacial lake outburst debris flow basin, it is indicated that no GLODF occurs in the drainage basin, but the identification result cannot indicate that the drainage basin does not occur other types of debris flows, that is, other types of debris flows may occur in the drainage basin. In addition, the drainage basin that the debris flow has occurred but the occurred debris flow is not determined whether being the GLODF is identified by the method provided by the disclosure; and it can be determined whether the occurred debris flow in the drainage basin is the GLODF. Moreover, when it is determined by the method of the disclosure that the to-be-identified drainage basin is the drainage basin that has occurred the GLODF, an upper reach (i.e., upstream) of the corresponding glacial lake needs to perform disaster prevention and control layout such as monitoring and early warning, so as to achieve a purpose of assisting preventing and managing disasters caused by the GLODF. A number of the channels in the to-be-identified drainage basin in the step 1 can be one or more, and the source particles include different types of rock particles distributed in the channels.

In the step 1, the calibrating a to-be-identified drainage basin, positioning channels of the to-be-identified drainage basin, and identifying source particles in the channels includes the following steps: obtaining an integrated condition of the to-be-identified drainage basin through multiple manners such as outdoor artificial exploration, unmanned aerial vehicle photographing, remote sensing satellite, etc., and the integrated condition including: a number, a distribution, and the slopes of the channels of the to-be-identified drainage basin, and a number, sizes, and a distribution of the rock particles in the channels; positioning the channels of the to-be-identified drainage basin through the integrated condition; and screening the source particles in the channels according to the number, the sizes, and the distribution of the rock particles in the channels. In an illustrated embodiment, the unmanned aerial vehicle photographing is used to obtain an overall high-definition image and a local high-definition image of the to-be-identified drainage basin; data related to the number, the distribution, and the slopes of the channels of the to-be-identified drainage basin is obtained through the overall high-definition image by using image recognition technology; and data related to the number, the sizes, and the distribution of the rock particles in any one of the channels is identified through the local high-definition image by using the image recognition technology. Therefore, the step 1 provides an initial basis for constructions of subsequent models (i.e., a slope coefficient model for the channels of the to-be-identified drainage basin, a particle size model corresponding to the source particles, and an identification model for the glacial lake outburst debris flow).

Step 2, a slope coefficient model for the channels of the to-be-identified drainage basin is constructed by using the slopes of the channels.

In an illustrated embodiment, the slope coefficient model for the channels of the to-be-identified drainage basin in the step 2 is expressed by the following formula:

$$C = \frac{1}{cos α - sin α} .$$

In the above formula, C represents a slope coefficient for the channels of the to-be-identified drainage basin; and a represents an average slope of the to-be-identified drainage basin. In the embodiment, the slope coefficient model for the channels of the to-be-identified drainage basin is constructed by using the average slope of the channels in the to-be-identified drainage basin, thereby making the slope coefficient model for the channels of the to-be-identified drainage basin comprehensively represent the slope condition in the to-be-identified drainage basin, and providing a reliable data source for subsequently obtaining an accurate identification result.

In another embodiment, in order to more accurately characterize the integrated condition of the channels in the to-be-identified drainage basin, the constructing a slope coefficient model for the channels of the to-be-identified drainage basin by using slopes of the channels further includes the following steps: determining the upper reach and a lower reach (i.e., downstream) of the to-be-identified drainage basin according to positioning results of the channels of the to-be-identified drainage basin, and setting the upper reach and the lower reach as a starting point and an ending point, respectively; segmenting the to-be-identified drainage basin by using the starting point and the ending point to obtain multiple segments; setting a slope weighting coefficient corresponding to each of the multiple segments according to a segmentation result; and summarizing the slopes of the channels in each of the multiple segments of the to-be-identified drainage basin and the slope weighting coefficients corresponding to the multiple segments to update the slope coefficient model for the channels of the to-be-identified drainage basin, thereby obtaining an updated slope coefficient model for the channels of the to-be-identified drainage basin as follows:

$$C = \frac{\sqrt{2}}{2 cos [ \frac{1}{n} {\sum }_{i = 1}^{n} {{k}_{i} ( \frac{1}{m} {\sum }_{t = 1}^{m} {θ}_{t} )}_{i} + \frac{π}{4} ]} .$$

In the above formula, C represents the slope coefficient for the channels of the to-be-identified drainage basin; i=1, 2, . . . , n, and n represents a total number of the multiple segments in the to-be-identified drainage basin; kᵢ≥1, and kᵢ represents the slope weighting coefficient corresponding to an i^{th} segment in the to-be-identified drainage basin;

$${( \frac{1}{m} {\sum }_{t = 1}^{m} {θ}_{t} )}_{i}$$

represents an average value of the slopes in the i^{th} segment of the to-be-identified drainage basin, t=1, 2, . . . , m, m represents a number of the channels contained in the corresponding segment of the to-be-identified drainage basin, and θₜ represents a slope of a t^{th} channel. Furthermore, the slope weighting coefficient mentioned above is changed according to an average water flow velocity of the channels in the corresponding segment, i.e., when the average water flow velocity flows more quickly, the slope weighting coefficient is greater; and when the average water flow velocity flows more slowly, the slope weighting coefficient is smaller. In addition, if there is no water in the channels of the corresponding segment or the water in the channels is stationary (i.e., no inflow or outflow), the slope weighting coefficient corresponding to the channels is 1. The updated slope coefficient model for the channels of the to-be-identified drainage basin proposed in the embodiment considers and quantifies the influence of water flowing in the channels on the slopes of the corresponding channels; and the slope coefficient obtained from the updated slope coefficient model for the channels of the to-be-identified drainage basin can more comprehensively represent the slope conditions in the to-be-identified drainage basin, providing a higher reliable data source for obtaining more accurate identification results in the future.

Step 3, an equivalent particle size model of the source particles is constructed by using geometric features of the source particles.

The geometric features in the step 3 include a length, a width, and a height of each of the source particles. In an illustrated embodiment, the equivalent particle size model of the source particles in the step 3 is expressed by the following formula:

$$D = {( \frac{6 abc}{π} )}^{1 / 3} .$$

In the above formula, D represents an equivalent particle size of the source particles; a represents an average length of the source particles, b represents an average width of the source particles, and c represents an average height of the source particles. In the embodiment, rock particles that can represent three-dimensional features of most of the rock particles in the channels of the to-be-identified drainage basin are selected as the source particles by combining actual conditions with experience of those skilled in the related art. Moreover, data related to the source particles is obtained by those skilled in the related art through using related measurement tools such as a tape measure.

In order to more accurately characterize the geometric features of the source particles, in another illustrated embodiment, the constructing an equivalent particle size model of the source particles by using geometric features of the source particles in the step 3 further includes the following steps: identifying types of the source particles in the channels, and obtaining distribution data of the types of the source particles; setting, according to the distribution data of the types of the source particles, source particles with a maximum number distributed in the channels as target source particles; setting a center position of the target source particles in contact with ground as an origin, setting a longest edge of edges that the target source particles are parallel to the ground as a horizontal axis, and setting a longitudinal axis according to the origin and the horizontal axis, and setting a vertical axis according to the origin, the horizontal axis, and the longitudinal axis, thereby establishing an evaluation coordinate system; projecting the target source particles on different two-dimensional planes of the evaluation coordinate system, respectively, and obtaining geometric features of the target source particles according to a projection result; obtaining average geometric features of the target source particles by summarizing and averaging the geometric features of the target source particles, which includes: the average length, the average width, and the average height; and updating the equivalent particle size model of the source particles by using the average geometric features, thereby obtaining an updated equivalent particle size model of the source particles as follows:

$$D = {{{Q}^{- 1} ( 6 / π )}^{1 / 3} [ {\sum }_{j = 1}^{Q} {a}_{j}^{′} {\sum }_{j = 1}^{Q} {b}_{j}^{′} {\sum }_{j = 1}^{Q} {c}_{j}^{′} ]}^{1 / 3} .$$

In the above formula, D represents the equivalent particle size of the source particles; j=1, 2, . . . , Q, and Q represents a total number of the target source particles; a′ⱼ represents a length of a j^{th} target source particle, b′ⱼ represents a width of the j^{th} target source particle, and c′ⱼ represents a height of the j^{th} target source particle.

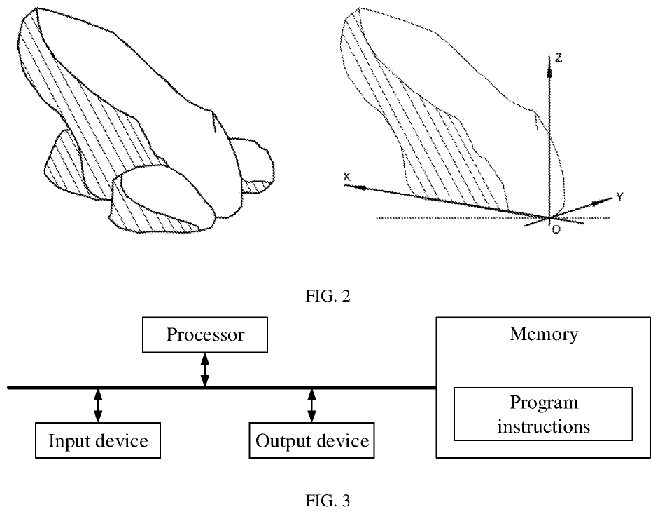

It should be understood that the types of the rock particles in the channels are multiple, meaning that the number of the rock particles is large, and if all types of the rock particles are used as the target source particles to perform corresponding data collection, an identification efficiency of the disclosure is correspondingly reduced while calculation amount is increased. In the embodiment, the source particles distributed widely are used as screening conditions for the target source particles, and the obtained target source particles are capable of greatly representing rock distribution characteristics in the channels, so that data reliability is also ensured while data acquisition work and the corresponding calculation amount are reduced, and the identification efficiency of the disclosure is improved. Furthermore, in the above embodiment, the evaluation coordinate system is established as shown in FIG. 2, the four rock particles illustrated in the left side of FIG. 2 are the source particles, and the intermediate rock particle is selected as the target source particle according to the overall rock distribution characteristics in the channels, that is, the irregular pattern illustrated in the right side of FIG. 2 is the target source particle, the transverse dashed line illustrated in FIG. 2 represents the ground, the O point illustrated in FIG. 2 represents the center position of the target source particle in contact with the ground, the X axis illustrated in FIG. 2 is the longest edge direction of the target source particle parallel to the ground (also referred as to the horizontal axis, the edge that the target source particle is parallel to the ground), the Y axis illustrated in FIG. 2 is constructed by referring to the O point and the X axis, and the Z axis takes the O point as the origin and is perpendicular to the XOY plane. The target source particle is projected on the XOY plane to obtain the length a′ of the target source particle and the width b′ of the target source particle respectively. Specially, the length is the longest diameter in the projection plane and the width is the longest diameter of the vertical length a′. Moreover, the target source particle is projected on the XOZ plane or YOZ plane to obtain the height c′ of the target source particle and the height c′ is the longest diameter of the projection parallel to the Z axis in the XOZ plane or YOZ plane.

Step 4, an identification model for the GLODF is constructed in combination with the slope coefficient model for the channels of the to-be-identified drainage basin and the equivalent particle size model of the source particles.

In an illustrated embodiment, the identification model for the GLODF constructed by combining the slope coefficient model for the channels of the to-be-identified drainage basin with the equivalent particle size model of the source particles is expressed by the following formula:

$$ω = \frac{{( D - 5.5 )}^{2}}{{( 4.5 )}^{2}} + {( C - 2 )}^{2} .$$

In the above formula, w represents an identification index for the GLODF; C represents the slope coefficient for the channels of the to-be-identified drainage basin obtained by the slope coefficient model for the channels of the to-be-identified drainage basin; and D represents the equivalent particle size of the source particles obtained by the equivalent particle size model of the source particles. Furthermore, in an illustrated embodiment, the slope coefficient model for the channels of the to-be-identified drainage basin is expressed by

$$C = \frac{1}{cos α - sin α} ,$$

in which C represents the slope coefficient for the channels of the to-be-identified drainage basin and a represents the average slope of the to-be-identified drainage basin. Moreover, the equivalent particle size model of the source particles is expressed by

$$D = {( \frac{6 abc}{π} )}^{1 / 3} ,$$

in which D represents the equivalent particle size of the source particles; a represents the average length of the source particles, b represents the average width of the source particles, and c represents the average height of the source particles.

In order to more accurately determine whether the to-be-identified drainage basin is the glacial lake outburst debris flow basin, in another illustrated embodiment, the identification model for the GLODF is constructed by using the updated slope coefficient model for the channels of the to-be-identified drainage basin and the updated equivalent particle size model of the source particles, i.e., in the aforementioned identification model for the GLODF, the slope coefficient model for the channels of the to-be-identified drainage basin is illustrated as follows:

$$C = \frac{\sqrt{2}}{2 cos [ \frac{1}{n} {\sum }_{i = 1}^{n} {{k}_{i} ( \frac{1}{m} {\sum }_{t = 1}^{m} {θ}_{t} )}_{i} + \frac{π}{4}} .$$

Specially, C represents the slope coefficient for the channels of the to-be-identified drainage basin; i=1, 2, . . . , n, and n represents the number of the multiple segments in the to-be-identified drainage basin; kᵢ≥1, and kᵢ represents the slope weighting coefficient corresponding to the i^{th} segment in the to-be-identified drainage basin;

$${( \frac{1}{m} {\sum }_{t = 1}^{m} {θ}_{t} )}_{i}$$

represents the average value of the slopes in the i^{th} segment of the to-be-identified drainage basin, t=1, 2, . . . , m, m represents the number of the channels contained in the corresponding segment of the to-be-identified drainage basin, and θₜ represents the slope of the t^{th} channel.

Moreover, the equivalent particle size model of the source particles is illustrated as follows:

$$D = {{{Q}^{- 1} ( 6 / π )}^{1 / 3} [ {\sum }_{j = 1}^{Q} {a}_{j}^{′} {\sum }_{j = 1}^{Q} {b}_{j}^{′} {\sum }_{j = 1}^{Q} {c}_{j}^{′} ]}^{1 / 3} .$$

In the above formula, D represents the equivalent particle size of the source particles; j=1, 2, . . . , Q, and Q represents the total number of the target source particles; a′ⱼ represents the length of the j^{th} target source particle, b′ⱼ represents the width of the j^{th} target source particle, and c′ⱼ represents the height of the j^{th} target source particle. It should be understood that in the identification model for the GLODF mentioned above, the slope coefficient model for the channels of the to-be-identified drainage basin and the equivalent particle size model of the source particles are two parameters that affect the accuracy of identification. The methods for obtaining the specific values corresponding to the parameters are not unique, and can be selected by those skilled in the related art according to actual needs.

Step 5, slope data corresponding to the channels is measured, and then the slope coefficient for the channels of the to-be-identified drainage basin is obtained by using the slope data in combination with the slope coefficient model for the channels of the to-be-identified drainage basin.

The method of obtaining the slope data containing one channel and the method of obtaining the slope data containing multiple channels are the same, but processing the slope data corresponding to the multiple channels is much more difficult than processing the slope data corresponding to the one channel. Meanwhile, the slope data corresponding to the channels measured in the step 5 can be obtained based on parameter data required by the slope coefficient model for the channels of the to-be-identified drainage basin.

Step 6, the geometric features of the source particles are measured, and then the equivalent particle size of the source particles of the to-be-identified drainage basin is obtained by using the geometric features of the source particles in combination with the equivalent particle size model of the source particles.

It should be understood that the geometric features of the source particles include the lengths, the widths, and the heights of the source particles, as well as average geometric features. In an illustrated embodiment, the average geometric features include the average length, the average width, and the average height. Similarly, the geometric features of the source particles measured in the step 6 can be obtained based on parameter data required by the equivalent particle size model of the source particles.

Step 7, based on the slope coefficient for the channels of the to-be-identified drainage basin, the equivalent particle size of the source particles, and the identification model for the GLODF, whether the to-be-identified drainage basin is the glacial lake outburst debris flow basin is determined.

In an illustrated embodiment, in the step 7, the determining, based on the slope coefficient for the channels of the to-be-identified drainage basin, the equivalent particle size of the source particles, and the identification model for the GLODF, whether the to-be-identified drainage basin is a glacial lake outburst debris flow basin includes the following steps: substituting the slope coefficient for the channels of the to-be-identified drainage basin and the equivalent particle size of the source particles into the identification model for the GLODF to obtain the identification index for the GLODF; determining, in response to the identification index for the GLODF being less than or equal to 1, the to-be-identified drainage basin as the glacial lake outburst debris flow basin; and determining, in response to the identification index for the GLODF being greater than 1, the to-be-identified drainage basin as a non-glacial lake outburst debris flow basin.

On a basis of considering the induced influences of the slopes of the channels and the particle sizes of the source particles on the GLODF, the disclosure provides the method for identifying the GLODF based on the slopes of the channels and the particle sizes of the source particles. Therefore, the method provided by the disclosure not only compensates for the deficiencies in identifying the GLODF in the related art, but also realizes the determination of the GLODF, which provides data basis for the disaster prevention and the control layout such as monitoring and early warning on the corresponding glacial lake, as well as assists preventing and managing the disasters caused by the GLODF. Meanwhile, the multiple parameters used in the method provided by the disclosure are easy and convenient to obtain, and the obtained parameters can be directly used on site, which saves engineering cost and improves working efficiency. Thus, the disclosure has high practical and promotional value in the technical field of environmental protection and disaster prevention and mitigation. In an embodiment, those skilled in the related art identify the debris flows occurred in multiple sites by using the method according to the disclosure, which is illustrated in the following Table 1:

| | Debris flow | | | | | |
|---|---|---|---|---|---|---|
| | Debris | | | | | |
| | flow | | | | | |
| | induced by | Debris | Debris | Debris | Debris | Debris |
| | Karakoram | flow | flow | flow | flow | flow |
| | Highway | induced | induced | induced | induced | induced |
| | (KKH) | by KKH | by KKH | by KKH | by KKH | by KKH |
| | K628 | K709 + 180 | K785 + 760 | K471 + 860 | K521 + 950 | K802 + 400 |
| | drainage | drainage | drainage | drainage | drainage | drainage |
| | basin | basin | basin | basin | basin | basin |
| Slope of | 14.6 | 5.5^{a} | 13.7 | 18.6 | 39.5 | 15.8 |
| channel (^{a}) | | | | | | |
| Slope | 1.4 | 1.11 | 1.36 | 1.59 | 7.51 | 1.45 |
| coefficient of | | | | | | |
| drainage | | | | | | |
| basin channel | | | | | | |
| C | | | | | | |
| Length a | 5 | 4 | 12 | 12 | 19 | 16 |
| (cm) | | | | | | |
| Width b (cm) | 6 | 3 | 6 | 10 | 7 | 8 |
| Height c | 4 | 2 | 4 | 5 | 3 | 8 |
| (cm) | | | | | | |
| Equivalent | 6.1 | 3.6 | 8.2 | 10.5 | 9.1 | 12.5 |
| particle size | | | | | | |
| of source | | | | | | |
| particles D | | | | | | |
| (cm) | | | | | | |
| Identification | 0.39 | 0.97 | 0.77 | 1.4 | 31.4 | 2.72 |
| index ω | | | | | | |
| Actuality | Yes | Yes | Yes | No | No | No |

Specially, according to the slope coefficient model

$$C = \frac{1}{cos α - sin α}$$

for the channels of the to-be-identified drainage basin and the equivalent particle size model

$$D = {( \frac{6 abc}{π} )}^{1 / 3}$$

of the source particles, those skilled in the related art can directly obtain the data required by the slopes of the channels, the length a, the width b and the height c recited in the above Table 1 on site, and then obtain the slope coefficient of drainage basin channel C (also referred as to the slope coefficient for the channels of the to-be-identified drainage basin) and the equivalent particle size of source particles D (also referred as to the equivalent particle size of the source particles) according to their corresponding calculation methods, thereby obtaining the corresponding identification index (i.e., whether being the glacial lake outburst debris flow basin) in combination with the identification model

$$ω = \frac{{( D - 5.5 )}^{2}}{{( 4.5 )}^{2}} + {( C - 2 )}^{2}$$

for the GLODF. Specially, when the identification index ω is less than or equal to 1, the to-be-identified drainage basin is determined as the glacial lake outburst debris flow basin; and when the identification index ω is greater than 1, the to-be-identified drainage basin is determined as the non-glacial lake outburst debris flow basin. Moreover, with reference to the “actuality” recited in the above Table 1, it can be seen that the theoretical result of the GLODF identified by the method provided by the disclosure is consistent with the actual field investigation result (i.e., the actuality). It can be seen therefrom that the method for identifying the GLODF provided by the disclosure has high precision and accuracy, can theoretically identify whether the debris flow disaster induced by the corresponding drainage basin belongs to the GLODF, and can provide theoretical support for disaster prevention and mitigation of the GLODF.

In order to better implement the above method, referring to FIG. 3, the disclosure further provides a system for identifying a GLODF, which includes: a processor, an input device, an output device, and a memory; the processor, the input device, the output device, and the memory are connected to each other; the memory is configured to store a computer program, the computer program includes program instructions, and the processor is configured to call the program instructions to execute the method for identifying the GLODF provided by the disclosure. The system for identifying the GLODF provided by the disclosure has a compact structure, is stable and rapid to operate, has extremely strong expansibility, and can well execute the method for identifying the GLODF.

Finally, it should be noted that the above embodiments are only used to illustrate the technical solutions of the disclosure, but are not limited to the disclosure. Although the disclosure has been described in detail with reference to the foregoing embodiments, it should be understood by those skilled in the related art that the technical solutions described in the foregoing embodiments may still be modified. In other words, some or all of the technical features of the foregoing embodiments can be equivalently replaced. However, these modifications or replacements do not depart from the scope of the technical solutions of the embodiments of the disclosure, which should be covered in the scope limited by the disclosure.

What is claimed is:

1. A method for identifying a glacial lake outburst debris flow (GLODF), comprising the following steps:
calibrating a to-be-identified drainage basin, positioning channels of the to-be-identified drainage basin, and identifying source particles in the channels;
constructing a slope coefficient model for the channels of the to-be-identified drainage basin by using slopes of the channels; wherein the slope coefficient model for the channels of the to-be-identified drainage basin is expressed by the following formula:
$$C = \frac{1}{cos α - sin α} ,$$
wherein C represents a slope coefficient for the channels of the to-be-identified drainage basin; and α represents an average slope of the to-be-identified drainage basin;
constructing an equivalent particle size model of the source particles by using geometric features of the source particles; wherein the equivalent particle size model of the source particles is expressed by the following formula:
$$D = {( \frac{6 abc}{π} )}^{1 / 3}$$
wherein D represents an equivalent particle size of the source particles; a represents an average length of the source particles, b represents an average width of the source particles, and c represents an average height of the source particles;
constructing an identification model for the GLODF in combination with the slope coefficient model for the channels of the to-be-identified drainage basin and the equivalent particle size model of the source particles; wherein the identification model for the GLODF is expressed by the following formula:
$$ω = \frac{{( D - 5.5 )}^{2}}{{( 4.5 )}^{2}} + {( C - 2 )}^{2} ,$$
wherein ω represents an identification index for the GLODF; C represents the slope coefficient for the channels of the to-be-identified drainage basin obtained by the slope coefficient model for the channels of the to-be-identified drainage basin; and D represents the equivalent particle size of the source particles obtained by the equivalent particle size model of the source particles;
measuring slope data corresponding to the channels, and then obtaining the slope coefficient for the channels of the to-be-identified drainage basin by using the slope data in combination with the slope coefficient model for the channels of the to-be-identified drainage basin;
measuring the geometric features of the source particles, and then obtaining the equivalent particle size of the source particles of the to-be-identified drainage basin by using the geometric features of the source particles in combination with the equivalent particle size model of the source particles; and
determining, based on the slope coefficient for the channels of the to-be-identified drainage basin, the equivalent particle size of the source particles, and the identification model for the GLODF, whether the to-be-identified drainage basin is a glacial lake outburst debris flow basin.

2. The method for identifying the GLODF as claimed in claim 1, wherein the to-be-identified drainage basin comprises: a drainage basin to be determined whether the GLODF occurs, and a drainage basin that a debris flow has occurred but the debris flow is not determined whether being the GLODF.

3. The method for identifying the GLODF as claimed in claim 1, wherein the calibrating a to-be-identified drainage basin, positioning channels of the to-be-identified drainage basin, and identifying source particles in the channels comprises the following steps:
obtaining an integrated condition of the to-be-identified drainage basin, wherein the integrated condition comprises: a number, a distribution, and the slopes of the channels of the to-be-identified drainage basin, and a number, sizes, and a distribution of rock particles in the channels;
positioning the channels of the to-be-identified drainage basin through the integrated condition; and
screening the source particles in the channels according to the number, the sizes, and the distribution of the rock particles in the channels.

4. The method for identifying the GLODF as claimed in claim 1, wherein the constructing a slope coefficient model for the channels of the to-be-identified drainage basin by using slopes of the channels further comprises the following steps:
determining an upper reach and a lower reach of the to-be-identified drainage basin according to positioning results of the channels of the to-be-identified drainage basin, and setting the upper reach and the lower reach as a starting point and an ending point, respectively;
segmenting the to-be-identified drainage basin by using the starting point and the ending point to obtain a plurality of segments;
setting a slope weighting coefficient corresponding to each of the plurality of segments according to a segmentation result; and
summarizing the slopes of the channels in each of the plurality of segments of the to-be-identified drainage basin and the slope weighting coefficients corresponding to the plurality of segments to update the slope coefficient model for the channels of the to-be-identified drainage basin.

5. The method for identifying the GLODF as claimed in claim 1, wherein the constructing an equivalent particle size model of the source particles by using geometric features of the source particles further comprises the following steps:
identifying types of the source particles in the channels, and obtaining distribution data of the types of the source particles;
setting, according to the distribution data of the types of the source particles, source particles with a maximum number distributed in the channels as target source particles;
setting a center position of the target source particles in contact with ground as an origin, setting an edge that the target source particles are parallel to the ground as a horizontal axis, and setting a longitudinal axis according to the origin and the horizontal axis, and setting a vertical axis according to the origin, the horizontal axis, and the longitudinal axis, thereby establishing an evaluation coordinate system;
projecting the target source particles on different two-dimensional planes of the evaluation coordinate system, respectively, and obtaining geometric features of the target source particles according to a projection result;
obtaining average geometric features of the target source particles by summarizing and averaging the geometric features of the target source particles, wherein the average geometric features comprise: an average length, an average width, and an average height of the target source particles; and
updating the equivalent particle size model of the source particles by using the average geometric features.

6. The method for identifying the GLODF as claimed in claim 1, wherein the determining, based on the slope coefficient for the channels of the to-be-identified drainage basin, the equivalent particle size of the source particles, and the identification model for the GLODF, whether the to-be-identified drainage basin is a glacial lake outburst debris flow basin comprises the following steps:
substituting the slope coefficient for the channels of the to-be-identified drainage basin and the equivalent particle size of the source particles into the identification model for the GLODF to obtain the identification index for the GLODF;
determining, in response to the identification index for the GLODF being less than or equal to 1, the to-be-identified drainage basin as the glacial lake outburst debris flow basin; and
determining, in response to the identification index for the GLODF being greater than 1, the to-be-identified drainage basin as a non-glacial lake outburst debris flow basin.

7. A system for identifying a GLODF, comprising: a processor, an input device, an output device, and a memory;
wherein the processor, the input device, the output device, and the memory are connected to each other; the memory is configured to store a computer program, the computer program comprises program instructions, and the processor is configured to call the program instructions to execute the method for identifying the GLODF as claimed in claim 1.
